(19) United States
(12) Patent Application Publication
(10) Pub. No.: US 2025/0212627 A1
(43) Pub. Date: Jun. 26, 2025

(54) DISPLAY SUBSTRATE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Wenbo CHEN, Beijing (CN); Tiaomei ZHANG, Beijing (CN); Ziyang YU, Beijing (CN); Zhiliang JIANG, Beijing (CN)

(21) Appl. No.: 18/850,021

(22) PCT Filed: Sep. 26, 2023
(86) PCT No.: PCT/CN2023/121605

§ 371 Date: Sep. 23, 2024

(30) Foreign Application Priority Data
Nov. 29, 2022 (CN) 202211515137.1

(51) Int. Cl. H10K 59/131; H10K 59/121

(52) U.S. Cl. CPC H10K 59/131; H10K 59/1213

(57) ABSTRACT

Disclosed are a display substrate and a display device. The display substrate includes: a base substrate, the base substrate including a display region and a bezel region on at least one side of the display region; a first electrode on the base substrate, where the first electrode extends from the display region to the bezel region; a first power bus between the layer where the first electrode is located and the base substrate, where the first power bus is in the bezel region and is electrically connected with the first electrode; and a first power line between the layer where the first electrode is located and the base substrate, where the first power line is in the display region, where the first power line is in the display region, is of a mesh structure, and is electrically connected with the first power bus.

### CROSS REFERENCES TO RELATED APPLICATIONS

The present application is a national phase entry under 35 U.S.C § 371 of International Application No. PCT/CN2023/121605, filed on Sep. 26, 2023, which claims priority to Chinese Patent Application No. 202211515137.1, entitled “Display Substrate and Display Device”, and filed to the China National Intellectual Property Administration on Nov. 29, 2022, the entire contents of which are incorporated herein by reference.

### TECHNICAL FIELD

The present disclosure relates to the technical field of display, in particular to a display substrate and a display device.

### BACKGROUND

In recent years, Organic Light Emitting Diodes (OLEDs) have gradually received more attention as a new type of flat panel display. It has excellent characteristics such as active luminescence, high luminescence brightness, high resolution, wide viewing angle, fast response speed, small thickness, low energy consumption, flexibility, wide temperature range, simple structure and process, etc., and has broad application prospects.

### SUMMARY

The display substrate and the display device provided by embodiments of the present disclosure are specifically described as follows.

In one aspect, an embodiment of the present disclosure provides a display substrate, including:
a base substrate, including a display region and a bezel region on at least one side of the display region;
a first electrode on the base substrate, where the first electrode extends from the display region to the bezel region;
a first power bus between a layer where the first electrode is located and the base substrate, where the first power bus is in the bezel region and is electrically connected with the first electrode;
a first power line between the layer where the first electrode is located and the base substrate, where the first power line is in the display region, is of a mesh structure, and is electrically connected with the first power bus.

In some embodiments, in the above-mentioned display substrate provided in embodiments of the present disclosure, the first power line includes:
a plurality of first sub-power lines, extending in a first direction and arranged in a second direction; and
a plurality of second sub-power lines, extending in the second direction and arranged in the first direction;
where the first sub-power lines are electrically connected with the second sub-power lines, the first sub-power lines are in a same layer as the second sub-power lines, or the first sub-power lines and the second sub-power lines are in different layers, and the first direction intersects with the second direction.

In some embodiments, in the above-mentioned display substrate provided in embodiments of the present disclosure, the display region includes a plurality of pixel columns and a plurality of dummy sub-pixel columns extending in the first direction and arranged in the second direction;
at least one dummy sub-pixel column is arranged between at least one pair of adjacent pixel columns, and the first sub-power lines are located in the dummy sub-pixel columns.

In some embodiments, in the above-mentioned display substrate provided in embodiments of the present disclosure, the display region includes a plurality of sub-pixel columns extending in the first direction and arranged in the second direction;
the first sub-power lines are in at least part of the plurality of sub-pixel columns.

In some embodiments, in the above-mentioned display substrate provided in embodiments of the present disclosure, the display region includes a plurality of sub-pixel rows and a plurality of dummy sub-pixel rows extending in the second direction and arranged in the first direction;
at least one dummy sub-pixel row is arranged between at least one pair of adjacent sub-pixel rows, and the second sub-power lines are located in the dummy sub-pixel rows.

In some embodiments, in the above-mentioned display substrate provided in embodiments of the present disclosure, the display region includes a plurality of sub-pixel rows extending in the second direction and arranged in the first direction;
the second sub-power lines are in at least part of the plurality of sub-pixel rows.

In some embodiments, in the above-mentioned display substrate provided in embodiments of the present disclosure, the bezel region includes a first bezel region and a second bezel region opposite to each other on both sides of the display region, and the first bezel region and the second bezel region both extend in the second direction;
the first power bus includes a first sub-power bus in the first bezel region and/or the second bezel region, and the first sub-power bus is electrically connected with the first sub-power line and the first electrode respectively.

In some embodiments, in the above-mentioned display substrate provided in embodiments of the present disclosure, the first sub-power bus includes a first branch and a second branch extending in the second direction, and a third branch connecting the first branch and the second branch;
where the first branch is arranged adjacent to the display region and is electrically connected with the first sub-power line, and the second branch is arranged on a side of the first branch away from the display region and is electrically connected with the first electrode.

In some embodiments, in the above-mentioned display substrate provided in embodiments of the present disclosure, a line width of the third branch is larger than a line width of the first branch; and the line width of the third branch is smaller than a line width of the second branch.

In some embodiments, the display substrate provided in embodiments of the present disclosure further includes: a transfer electrode between a layer where the first power bus is located and the layer where the first electrode is located;
where the transfer electrode connects the second branch and the first electrode.

In some embodiments, the display substrate provided in embodiments of the present disclosure further includes: a second electrode between the layer where the first power bus is located and the layer where the first electrode is located;
where the transfer electrode is provided in a same layer and with a same material as the second electrode.

In some embodiments, the display substrate provided in embodiments of the present disclosure further includes: a second power bus in the first bezel region and/or the second bezel region; where the second power bus includes: a main body portion extending in the second direction; and the main body portion is in a region enclosed by the first branch, the second branch and the third branch.

In some embodiments, in the above-mentioned display substrate provided in embodiments of the present disclosure, the second power bus further includes at least one lead-out portion on a side of the main body portion away from the display region, and the second branch is disconnected at a position of the lead-out portion.

In some embodiments, in the above-mentioned display substrate provided in embodiments of the present disclosure, the second power bus and the first sub-power bus are insulated from each other and arranged in different layers.

In some embodiments, in the above-mentioned display substrate provided in embodiments of the present disclosure, the bezel region includes a third bezel region and a fourth bezel region opposite to each other on both sides of the display region, and the third bezel region and the fourth bezel region both extend in the first direction;
the first power bus includes a second sub-power bus in the third bezel region and/or the fourth bezel region, and the second sub-power bus is electrically connected with the second sub-power line.

In some embodiments, the display substrate provided in embodiments of the present disclosure further includes: a connecting line in the third bezel region and/or the fourth bezel region; where the connecting line is connected between the second sub-power bus and the second sub-power line.

In some embodiments, in the above-mentioned display substrate provided in embodiments of the present disclosure, the connecting line, the second sub-power bus, and the second sub-power line are arranged in different layers.

In some embodiments, the display substrate provided in embodiments of the present disclosure further includes: a gate drive circuit in the third bezel region and/or the fourth bezel region; where the gate drive circuit and the second sub-power bus are arranged in different layers, and an orthographic projection of the gate drive circuit on the base substrate is located within an orthographic projection of the second sub-power bus on the base substrate.

In some embodiments, the display substrate provided in embodiments of the present disclosure further includes: a first active layer, a first gate metal layer, a second gate metal layer, a second active layer, a third gate metal layer, a first source-drain metal layer, a second source-drain metal layer and a third source-drain metal layer sequentially arranged on the base substrate and insulated from each other;
where the first sub-power line and the second sub-power line are arranged in at least one of: the first gate metal layer, the second gate metal layer, the third gate metal layer, the first source-drain metal layer, the second source-drain metal layer or the third source-drain metal layer.

On the other hand, an embodiment of the present disclosure provides a display device, including the above-mentioned display substrate provided by embodiments of the present disclosure.

### BRIEF DESCRIPTION OF FIGURES

FIG. 1 is a schematic structural diagram of a display substrate provided in an embodiment of the present disclosure.

FIG. 2 is another schematic structural diagram of a display substrate provided in an embodiment of the present disclosure.

FIG. 3 is another schematic structural diagram of a display substrate provided in an embodiment of the present disclosure.

FIG. 4 is a schematic structural diagram of the first power line and the second power line in the M region of FIG. 3.

FIG. 5 is another schematic structural diagram of a display substrate provided in an embodiment of the present disclosure.

FIG. 6 is another schematic structural diagram of a display substrate provided in an embodiment of the present disclosure.

FIG. 7 is another schematic structural diagram of a display substrate provided in an embodiment of the present disclosure.

FIG. 8 is a schematic structural diagram of a first power line in the N region of FIG. 7.

FIG. 9 is another schematic structural diagram of a display substrate provided in an embodiment of the present disclosure.

FIG. 10 is a schematic structural diagram of a first power line, a first power bus, and a second power bus in the O region of FIG. 1 and FIG. 3.

FIG. 11 is a schematic structural diagram of a second sub-power bus, a connecting line, and a first power line in the P region of FIG. 1 and FIG. 3.

### DETAILED DESCRIPTION

In order to make the purpose, technical solutions and advantages of embodiments of the present disclosure more clear, the technical solutions of embodiments of the present disclosure will be clearly and completely described below in conjunction with the drawings of embodiments of the present disclosure. It should be noted that in the accompanying drawings, the thickness of a layer, a film, a panel, an area, etc., is enlarged for clarity. In the disclosure, an exemplary embodiment is described by referring to a cross-sectional diagram as a schematic diagram of an idealized embodiment. In this way, deviations from the shape of the drawing as a result of, for example, manufacturing techniques and/or tolerances are expected. Thus, embodiments described in the present disclosure should not be construed as being limited to the specific shape of an area as shown in the present disclosure, but rather include deviations in shape caused by, for example, manufacturing. For example, regions illustrated or described as flat may typically have rough and/or non-linear features; sharp corners illustrated may be rounded, etc. Thus, the areas shown in the drawings are schematic in nature, and their dimensions and shapes do not purport to be the exact shape of the areas shown, do not reflect true proportions, and are intended to be illustrative of the present disclosure only. And the same or similar labels throughout represent the same or similar components or components with the same or similar functions. In order to keep the following description of embodiments of the present disclosure clear and concise, the present disclosure omits detailed descriptions of known functions and known components.

The technical or scientific terms used in the disclosure have the ordinary meanings as understood by those of ordinary skill in the art to which the disclosure belongs unless defined otherwise. The words “first”, “second”, etc. used in the disclosure do not denote any order, quantity, or importance, but are merely used for distinguishing between different constituent parts. The words “include”, or “comprise”, etc. mean that elements or items before the word encompass elements or items listed after the word and their equivalents, and do not exclude other elements or items. The words “connection”, “connecting”, etc. are not limited to physical or mechanical connection, but can include electrical connection whether direct or indirect. The words “inside”, “outside”, “upper”, “lower”, etc. are merely used to represent a relative position relation. After an absolute position of an object described is changed, the relative position relation may also be changed accordingly.

In the following description, when an element or layer is referred to as being “on” or “connected with” another element or layer, the element or layer may be directly on or directly connected with the other element or layer, or intervening elements or layers may be present. When an element or layer is referred to as being “arranged on one side of” another element or layer, the element or layer may be directly on one side of the other element or layer, directly connected with the other element or layer, or intervening elements or layers may be present. However, when an element or layer is referred to as being “directly on” or “directly connected with” another element or layer, there are no intervening elements or layers present. The term “and/or” includes any and all combinations of one or more of the associated listed items.

The word “about” or “approximately” as used in the disclosure are inclusive of the stated value and mean within an acceptable range of deviation for the particular value as determined by one of ordinary skill in the art taking into account the measurements in question and errors associated with the measurement of the particular quantity (i.e., the limitations of the measurement system). For example, “approximately” may mean within one or more standard deviations (eg, ±10%) relative to the stated value.

With the popularization of Active Matrix Organic Light Emitting Diode (AMOLED) in small-sized displays, the demand for active matrix organic light emitting diode in medium to large-sized car displays, laptops and tablets is gradually increasing due to their rich color gamut and high contrast. In the related art, a first power bus (VSS) is usually set in the bezel region, and the first power bus is electrically connected with a planar cathode extending from the display region to the bezel region by via holes in the bezel region. Since the current density on the first power bus is relatively large, the first power bus is generally wider, which is not conducive to achieving a narrow border. Moreover, as the size of the organic light emitting display driven by the active matrix increases, the wiring length and resistance of the first power bus also increase, resulting in a larger loading of the first power bus and a corresponding large voltage drop (IR-Drop). The power signal transmission on the first power bus is delayed, affecting the display uniformity.

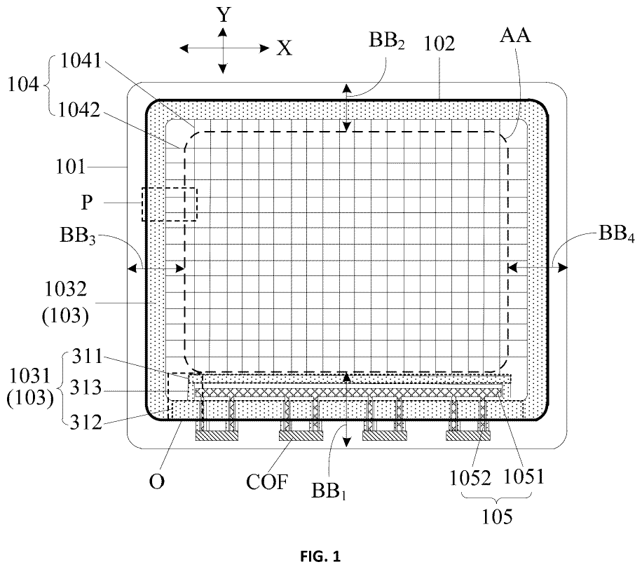

In order to improve the above technical problems existing in the related art, the present disclosure provides a display substrate, as shown in FIG. 1, including:
a base substrate 101, including a display region AA and a bezel region BB arranged on at least one side of the display region AA;
a first electrode 102, arranged on the base substrate 101, where the first electrode 102 extends from the display region AA to the bezel region BB; in some embodiments, the first electrode 102 is the cathode of the light-emitting device;
a first power bus 103, arranged between a layer where the first electrode 102 is located and the base substrate 101, where the first power bus 103 is located in the bezel region BB and is electrically connected with the first electrode 102; in some embodiments, the first power bus 103 is a low-level power line VSS;
a first power line 104, arranged between the layer where the first electrode 102 is located and the base substrate 101, where the first power line 104 is located in the display region AA, the first power line 104 is a mesh structure and is electrically connected with the first power bus 103.

In the above-mentioned display substrate provided in embodiments of the present disclosure, by adding a first power line 104 with a mesh structure in the display region AA, and setting the first power line 104 to be electrically connected with the first power bus 103 in the bezel region BB, the first power line 104 with a mesh structure can be used to share the current, thereby effectively alleviating the large current density on the first power bus 103, so that the first power bus 103 can be made narrower, which is conducive to the narrow border design. And, the power signal provided by the first power bus 103 is transmitted in a dispersed manner through the first power line 104 with a mesh structure, which can effectively reduce the voltage drop of the power signal on the transmission path and improve the uniformity of the power signal, thereby effectively improving the display uniformity.

In some embodiments, in the above-mentioned display substrate provided in embodiments of the present disclosure, as shown in FIG. 1, the first power line 104 includes a plurality of first sub-power lines 1041 extending in the first direction Y and arranged in the second direction X, and a plurality of second sub-power lines 1042 extending in the second direction X and arranged in the first direction Y. The first sub-power lines 1041 may be electrically connected with the second sub-power lines 1042, the first sub-power lines 1041 are in a same layer as the second sub-power lines 1042, or the first sub-power lines 1041 and the second sub-power lines 1042 are in different layers, and the first direction Y intersects with the second direction X. In some embodiments, when the first sub-power line 1041 and the second sub-power line 1042 are electrically connected on the same layer, the first sub-power line 1041 and the second sub-power line 1042 can be arranged integrally; when the first sub-power line 1041 and the second sub-power line 1042 are electrically connected on different layers, the first sub-power line 1041 and the second sub-power line 1042 can be electrically connected by via hole, or transferred through other conductive parts, which is not limited here.

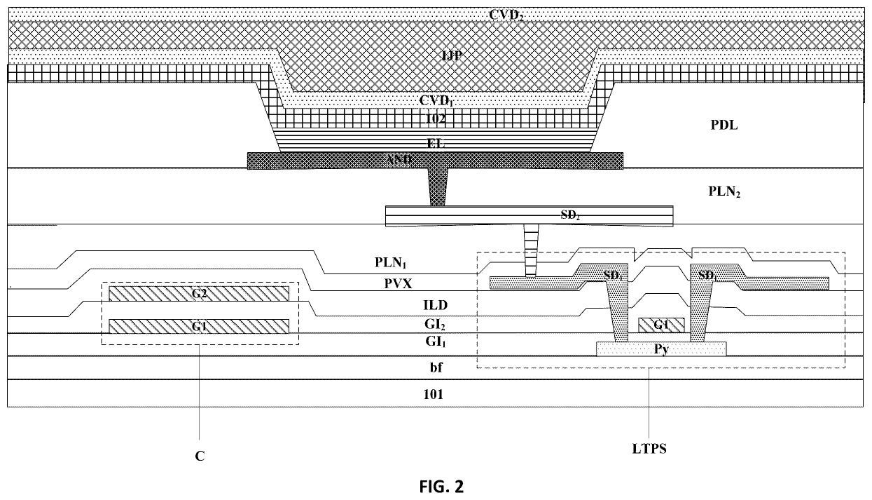

Considering that the display substrate itself has multiple conductive layers, in order to reduce the number of film layers, one or more of these conductive layers can be used to make the first sub-power line 1041 and the second sub-power line 1042. The display substrate may be a low temperature polycrystalline oxide (LTPO) substrate, as shown in FIG. 2, the display substrate includes a first active layer (Py), a first gate metal layer (G1), a second gate metal layer (G2), a second active layer (not shown in the figure), a third gate metal layer (G3, not shown in the figure), a first source-drain metal layer (SD₁), a second source-drain metal layer (SD₂) and a third source-drain metal layer (SD₃, not shown in the figure) which are sequentially arranged on a base substrate 101 and insulated from each other. In some embodiments, a first sub-power line 1041 and a second sub-power line 1042 are arranged on at least one of: the first gate metal layer (G1), the second gate metal layer (G2), the third gate metal layer (G3), the first source-drain metal layer (SD₁), the second source-drain metal layer (SD₂) and the third source-drain metal layer (SD₃). In some embodiments, the first sub-power line 1041 is arranged on the first source-drain metal layer (SD₁), the second source-drain metal layer (SD₂) or the third source-drain metal layer (SD₃), and the second sub-power line 1042 is arranged on the second gate metal layer (G2), the third gate metal layer (G3), the first source-drain metal layer (SD₁), the second source-drain metal layer (SD₂) or the third source-drain metal layer (SD₃), which is not limited here.

In some embodiments, as shown in FIG. 2, the structure of the display substrate provided by the present disclosure may include, from bottom to top, a base substrate 101, a buffer layer (bf), a first active layer (Py), a first gate insulating layer (GI₁), a first gate metal layer (G1), a second gate insulating layer (GI₂), a second gate metal layer (G2), an insulating layer (not shown in the figure), a second active layer (not shown in the figure), a third gate insulating layer (G13, not shown in the figure), a third gate metal layer (G3, not shown in the figure), an interlayer dielectric layer (ILD), a first source-drain metal layer (SD₁), a first planarization layer (PLN₁), a second source-drain metal layer (SD₂), a second planarization layer (PLN₂), a third source-drain metal layer (SD₃, not shown in the figure), a third planarization layer (PLN₃), an anode (AND), a light-emitting functional layer (EL), a cathode (for example, a first electrode 102), a first inorganic encapsulation layer (CVD₁), an organic encapsulation layer (IJP) and a second inorganic encapsulation layer (CVD₂).

Among them, the base substrate 101 can be a flexible base substrate, for example, a plastic substrate with excellent heat resistance and durability, such as polyethylene ether phthalate, polyarylic compounds, polyimide (PI), polyethylene terephthalate (PET), polycarbonate (PC), cyclic olefin polymer (COP), cellulose acetate propionate (CAP), polyether sulfone (PES), polyacrylate (PAR), polyetherimide (PEI), polyethylene naphthalate (PEN), polyphenylene sulfide (PPS), polypropylene ester, cellulose triacetate (TAC), etc. The base substrate 101 can be a rigid base substrate, such as a glass substrate, which is not limited here.

The materials of the buffer layer, the first gate insulating layer (GI₁), the second gate insulating layer (GI₂), the insulating layer (not shown in the figure), the third gate insulating layer (GI₃), and the interlayer dielectric layer (ILD) may include inorganic materials such as silicon oxide, silicon nitride, and silicon oxynitride, and their film layer structure may be a single-layer structure or a stacked-layer structure, which is not limited here.

The materials of the first planarization layer (PLN₁), the second planarization layer (PLN₂), the third planarization layer (PLN₃), and the pixel definition layer (PDL) can be organic insulating materials such as polyacrylic resin, polyepoxy acrylic resin, photosensitive polyimide resin, polyester acrylate, polyurethane acrylate resin, phenolic epoxy acrylic resin, etc., which are not limited here.

The materials of the first gate metal layer (G1), the second gate metal layer (G2), the third gate metal layer (G3, not shown in the figure), the first source-drain metal layer (SD₁), the second source-drain metal layer (SD₂) and the third source-drain metal layer (SD₃, not shown in the figure) can be molybdenum (Mo), aluminum (AI), titanium (Ti) and other materials suitable for dry etching. In some embodiments, these metal film layers can be single-layer metals or stacked metals. In some embodiments, the gate metal layer is a single-layer molybdenum metal, and the source-drain metal layer is a triple-layer composed of titanium metal layer/aluminum metal layer/titanium metal layer.

The light-emitting functional layer (EL) includes but is not limited to a hole injection layer, a hole transport layer, an electron blocking layer, a light-emitting material layer, a hole blocking layer, an electron transport layer, an electron injection layer, and the like. The luminescent material layer may be a red light material layer, a green light material layer, a blue light material layer, a yellow light material layer, a white light material layer, etc.; and the luminescent material layer may include small molecule organic materials or polymer molecules, and may be a fluorescent luminescent material, a phosphorescent luminescent material, etc.

The material of the anode (AND) may include at least one transparent conductive oxide material including indium tin oxide (ITO), indium zinc oxide (IZO), zinc oxide (ZnO), etc. In addition, the anode may include a metal with high reflectivity as a reflective layer, such as silver (Ag). The material of the cathode (eg, the first electrode 102) may include metal materials such as lithium (Li), aluminum (AI), magnesium (Mg), and silver (Ag).

The materials of the first inorganic encapsulation layer (CVD₁) and the second inorganic encapsulation layer (CVD₂) may include silicon nitride, silicon oxide, silicon oxynitride and other inorganic materials with high density that can prevent the intrusion of water, oxygen, etc. The material of the organic encapsulation layer (IJP) may be a polymer material containing a desiccant or a polymer material that can block water vapor, such as a polymer resin, etc., to flatten the surface of the display substrate, and to relieve the stress of the first inorganic encapsulation layer and the second inorganic encapsulation layer, and may also include a desiccant and other water-absorbing materials to absorb water, oxygen and other substances that invade the interior.

The low-temperature polycrystalline oxide (LTPO) substrate includes two types of thin-film transistors, namely, low-temperature polycrystalline silicon thin-film transistors (LTPS) and oxide thin-film transistors (Oxide), as well as components such as capacitors (C). Among them, low-temperature polycrystalline silicon thin-film transistors have the advantages of high mobility and fast charging, while oxide thin-film transistors have the advantages of low leakage current. Integrating low-temperature polycrystalline silicon thin-film transistors and oxide thin-film transistors on a display substrate can utilize the advantages of both to achieve low-frequency driving and reduce power consumption, thereby improving display quality. In some embodiments, the first active layer may be an active layer of a low-temperature polycrystalline silicon thin film transistor, such as low-temperature polycrystalline silicon; the second active layer may be an active layer of an oxide thin film transistor, such as indium gallium zinc oxide.

The first gate metal layer (G1) can be used to form a gate of the low-temperature polycrystalline silicon thin film transistor and a first electrode plate of the capacitor; the second gate metal layer (G2) can be used to form a bottom gate of the oxide thin film transistor and a second electrode plate of the capacitor; the third gate metal layer (G3) can be used to form a top gate of the oxide thin film transistor; the first source-drain metal layer (SD₁) can be used to form the source-drain electrodes of the low-temperature polycrystalline silicon thin film transistor and the source-drain electrodes of the oxide thin film transistor; the second source-drain metal layer (SD₂) and the third source-drain metal layer (SD₃) are used to form signal lines such as data lines. It can be seen that these conductive layers of the display substrate itself usually form thin film transistors, capacitors and other elements of the pixel driving circuit in the display region AA. Therefore, in order to simplify the wiring design of a single conductive layer, the present disclosure preferably sets the first sub-power line 1041 and the second sub-power line 1042 in different film layers.

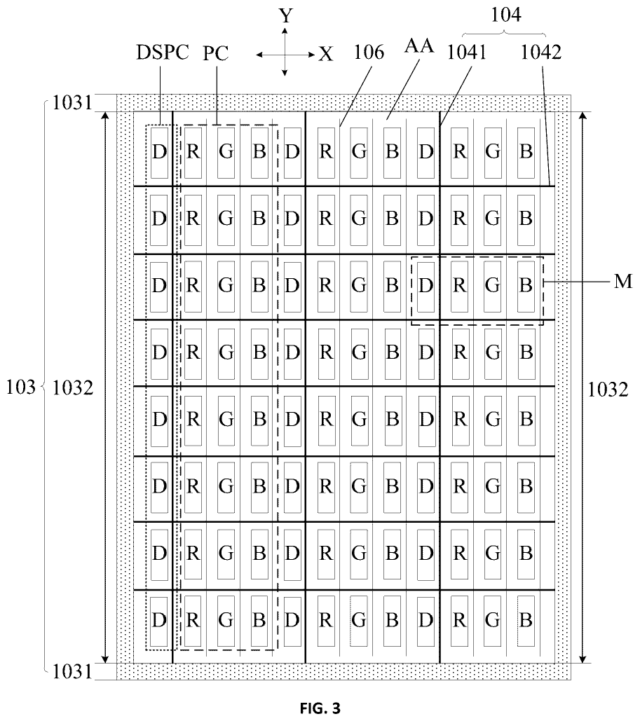

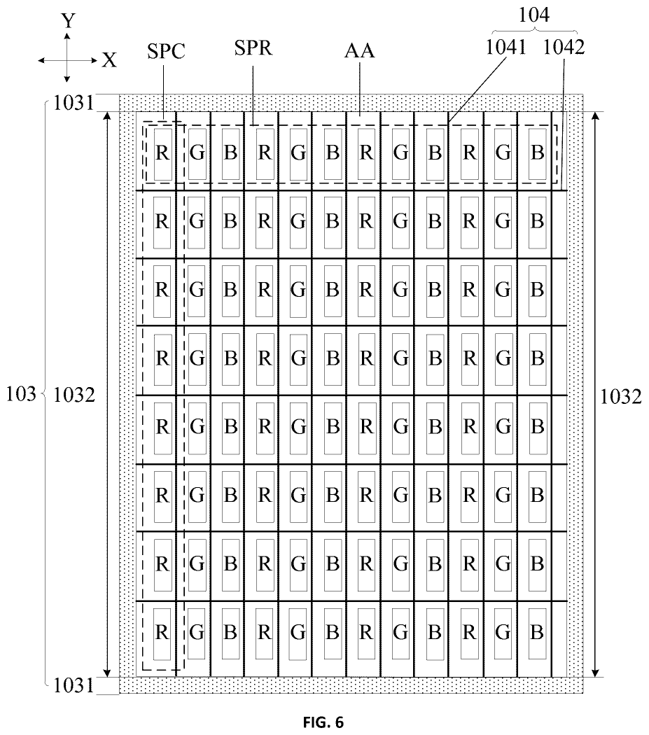

In some embodiments, in the display substrate provided in embodiments of the present disclosure, the first sub-power line 1041 can be arranged in the following two wiring methods, one of which is shown in FIGS. 3 to 5. The display region AA includes a plurality of pixel columns PC and a plurality of dummy sub-pixel columns DSPC extending in the first direction Y and arranged in the second direction X. At least one dummy sub-pixel column DSPC is arranged between at least one pair of adjacent pixel columns PC. In order to avoid affecting the normal display function of the pixel column PC, the first sub-power lines 1041 can be arranged in the dummy sub-pixel columns DSPC. Another wiring method is shown in FIG. 6, the display region AA includes a plurality of sub-pixel columns SPC extending in the first direction Y and arranged in the second direction X, and no dummy sub-pixel column DSPC is arranged. In this case, the first sub-power line 1041 can be arranged in a region where at least part of the plurality of sub-pixel columns SPC is located. In some embodiments, a first sub-power line 1041 is arranged in a region where each sub-pixel column SPC is located. Since it is only necessary to add the first sub-power line 1041 in the region where at least part of the sub-pixel columns SPC is located without adding the dummy sub-pixel column DSPC, the solution is relatively simple.

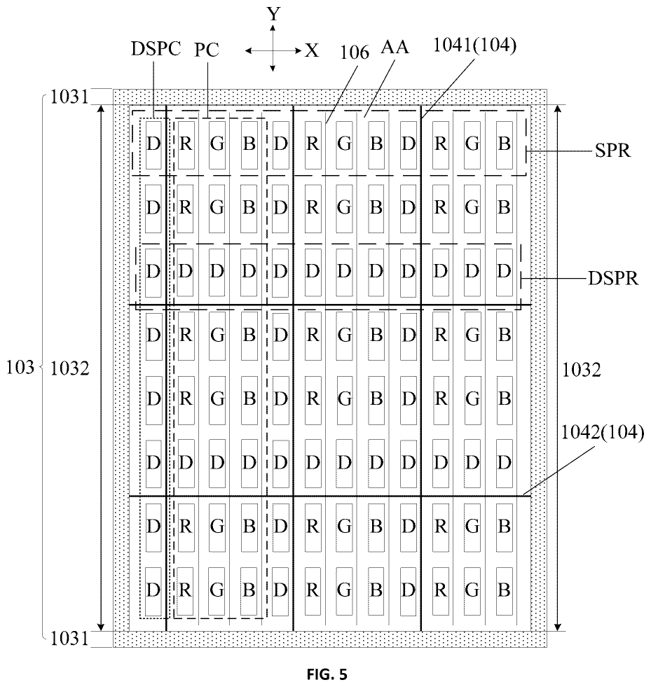

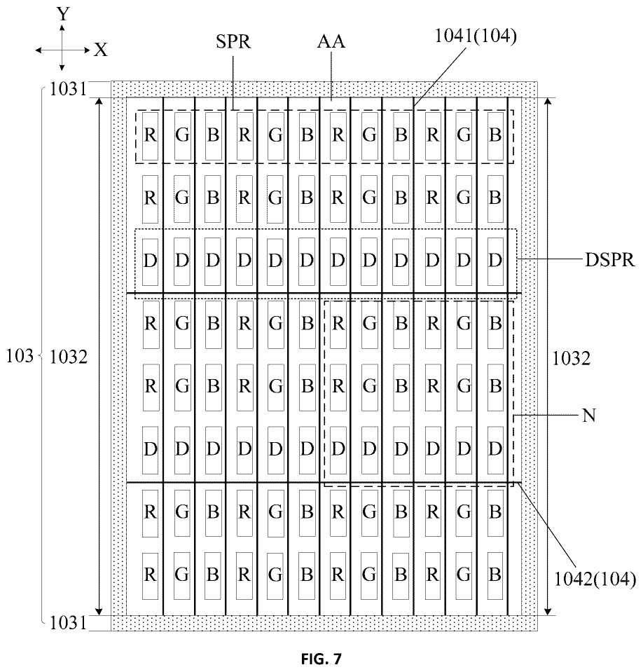

In some embodiments, in the above-mentioned display substrate provided in embodiments of the present disclosure, the second sub-power line 1042 can be arranged by the following two wiring methods, one of which is shown in FIGS. 5 and 7. The display region AA includes a plurality of sub-pixel rows SPR and a plurality of dummy sub-pixel rows DSPR extending in the second direction X and arranged in the first direction Y. At least one dummy sub-pixel row DSPR is arranged between at least one pair of adjacent sub-pixel rows SPR. In order to avoid interfering with the normal display function of the sub-pixel row SPR, the second sub-power lines 1042 can be located in the dummy sub-pixel row DSPR. Another wiring method is shown in FIG. 6, the display region AA includes a plurality of sub-pixel rows SPR extending in the second direction X and arranged in the first direction Y, and no dummy sub-pixel row DSPR is arranged. In this case, the second sub-power line 1042 can be arranged in a region where at least part of the sub-pixel rows SPR is located. In some embodiments, a second sub-power line 1042 is arranged in a region where each sub-pixel row SPR is located. Since it is only necessary to add the second sub-power line 1042 at in as region where at least part of the sub-pixel rows SPR is located without adding the dummy sub-pixel row DSPR, the solution is relatively simple.

In some embodiments, each pixel column PC may include a plurality of pixels, each pixel includes a plurality of sub-pixels, sub-pixels in the same column constitute a sub-pixel column SPC, and sub-pixels in the same row constitute a sub-pixel row SPR. In some embodiments, each pixel may include a red sub-pixel R, a green sub-pixel G, and a blue sub-pixel B, so that red, green, and blue can be mixed to achieve color display. In some embodiments, the pixel may also include a red sub-pixel R, a green sub-pixel G, a blue sub-pixel B, and a white sub-pixel W, etc., so that red, green, blue, and white can be mixed to achieve color display. Of course, in practical applications, the luminous color of each sub-pixel in a pixel can be designed and determined according to the actual application environment, and is not limited here. In addition, the dummy sub-pixel column DSPC and the dummy sub-pixel row DSPR may include multiple dummy sub-pixels D, and like the red sub-pixel R, the green sub-pixel G, the blue sub-pixel B and other sub-pixels, the dummy sub-pixel D may also include a pixel driving circuit and a light-emitting device, and to ensure that each driving signal in the display region AA has the same load, the pixel driving circuit and the layout of the light-emitting device may be made the same in the sub-pixel and the dummy sub-pixel D. The difference is that, in the red sub-pixel R, the green sub-pixel G, the blue sub-pixel B and other sub-pixels, the pixel driving circuit is electrically connected with the light-emitting device, and the light-emitting device can be driven to emit light by the pixel driving circuit, but in the dummy sub-pixel D, the pixel driving circuit is not electrically connected with the light-emitting device, and therefore, the dummy sub-pixel D does not emit light.

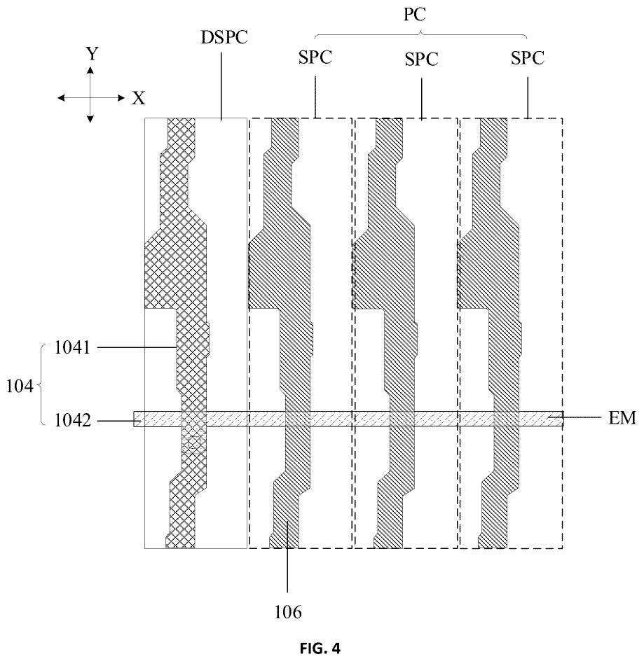

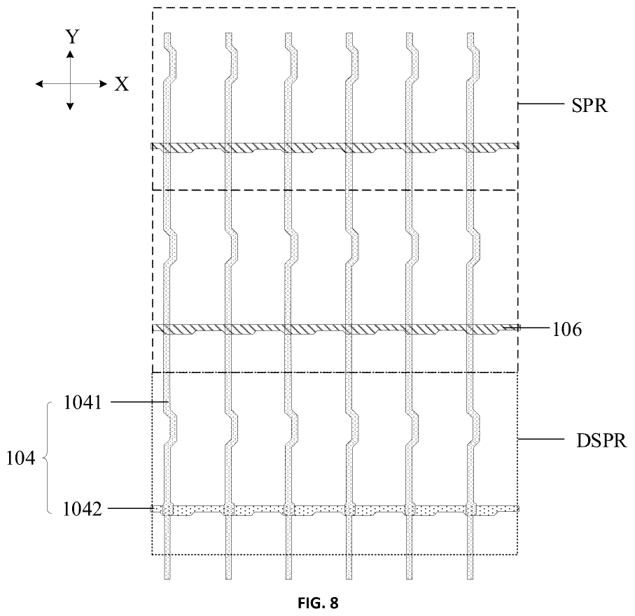

Continuing to refer to FIG. 4, it can be seen that the display substrate may further include a light-emitting control signal line (EM). In some embodiments, the light-emitting control signal line (EM) is located in the first gate metal layer (G1). In order not to affect the related wiring space of the first gate metal layer (G1), the second sub-power line 1042 may be arranged to be arranged in the third gate metal layer (G3). In some embodiments, the orthographic projection of the second sub-power line 1042 on the base substrate 101 and the orthographic projection of the light-emitting control signal line (EM) on the base substrate 101 can overlap with each other. Due to the presence of a second gate insulating layer (GI₂), an insulating layer (not shown in the figure), and a third gate insulating layer (GI₃) between the second sub-power line 1042 and the light-emitting control signal line (EM), even if their orthographic projections overlap, the coupling capacitance between them is small and will not cause significant interference with each other. Of course, in some embodiments, the orthographic projection of the second sub-power line 1042 on the base substrate 101 and the orthographic projection of the light emitting control signal line (EM) on the base substrate 101 cannot overlap with each other, which is not limited here. Continuing to refer to FIG. 8, it can be seen that the display substrate may further include a second power line 106 that is arranged substantially parallel to the second sub-power line 1042 (i.e., parallel or within an error range caused by factors such as manufacturing and measurement). In some embodiments, the second power line 106 is arranged on the same layer as the second sub-power line 1042, and the second power line 106 may be arranged in a region where the sub-pixel row SPR is located and loaded with a high-level power signal (VDD).

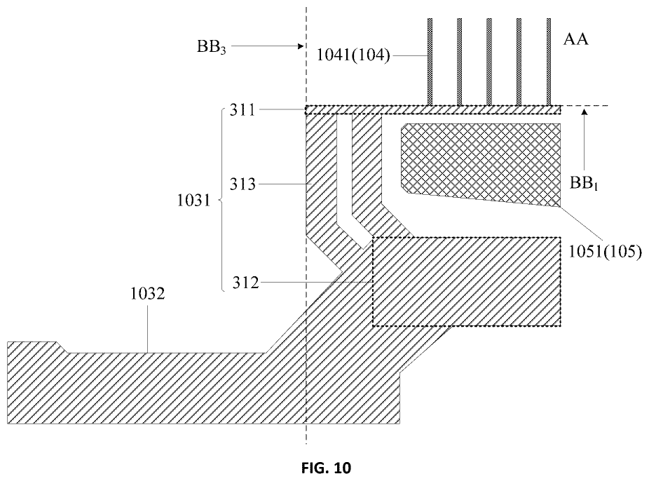

In some embodiments, in the above-mentioned display substrate provided in embodiments of the present disclosure, as shown in FIGS. 1, 9 and 10, the bezel region BB includes a first bezel region BB₁ and a second bezel region BB₂ opposite to each other on both sides of the display region AA, and the first bezel region BB₁ and the second bezel region BB₂ both extend in the second direction X; the first power bus 103 includes a first sub-power bus 1031 located in the first bezel region BB₁ and/or the second bezel region BB₂, and the first sub-power bus 1031 is electrically connected with the first sub-power line 1041 and the first electrode 102 respectively. When the first sub-power bus 1031 is arranged in both the first bezel region BB₁ and the second bezel region BB₂, the influence of the voltage drop of the power signal in the transmission path on the display uniformity can be better reduced.

In some embodiments, in the above-mentioned display substrate provided in embodiments of the present disclosure, the first sub-power bus 1031 can be arranged in the first source-drain metal layer (SD₁), and the first sub-power line 1041 can be located in the second source-drain metal layer (SD₂), and the first sub-power bus 1031 can be electrically connected with the first sub-power line 1041 by via hole. The first sub-power bus 1031 can be connected with the first electrode 102 (for example, the cathode of the light-emitting device) through a transfer electrode that is arranged in the same layer and material as the second electrode (for example, the anode of the light-emitting device). In some embodiments, the transfer electrode is a hollow structure, which can reduce the overlapping area between the transfer electrode and the second power bus 105, thereby avoiding the overlap of large currents on the second power bus 105 and the first power bus 103.

It should be noted that, in the present disclosure, “arranged in the same layer” refers to a layer structure formed by using the same film-forming process to form a film layer for making a specific pattern, and then using the same mask plate through a single patterning process. That is, one patterning process corresponds to one mask (also called a photo-mask). Depending on the specific graphics, a composition process may include multiple exposure, development or etching processes, and the specific graphics in the formed layer structure may be continuous or discontinuous. These specific graphics may be at the same height or have the same thickness, or at different heights or have different thicknesses.

In some embodiments, in the above-mentioned display substrate provided in embodiments of the present disclosure, as shown in FIGS. 1, 9 and 10, the first sub-power bus 1031 may include a first branch 311 and a second branch 312 extending in the second direction X, and a third branch 313 connecting the first branch 311 and the second branch 312; where the first branch 311 is arranged adjacent to the display region AA and is electrically connected with the first sub-power line 1041, and the second branch 312 is arranged on a side of the first branch 311 away from the display region AA and is electrically connected with the first electrode 102 and a bonding Pad of a circuit board such as a chip on film (COF). In some embodiments, in order to minimize the bezel region, the line width of the first branch 311 electrically connected with the first sub-power line 1041 can be arranged to be slightly smaller, for example, the line width of the first branch 311 is smaller than the line width of the third branch 313. In order to enhance the electrical connection effect between the second branch 312 and the first electrode 102, the line width of the second branch 312 can be set to be slightly larger, for example, the line width of the second branch 312 is larger than the line width of the third branch 313. In other words, the line width of the third branch 313 can be larger than the line width of the first branch 311 and smaller than the line width of the second branch 312. In some embodiments, the line width of the second section 312 is more than 4 times the line width of the first section 311, so as to facilitate lapping the cathode (eg, the first electrode 106) only on the second section 312, without lapping the cathode on the first section 311.

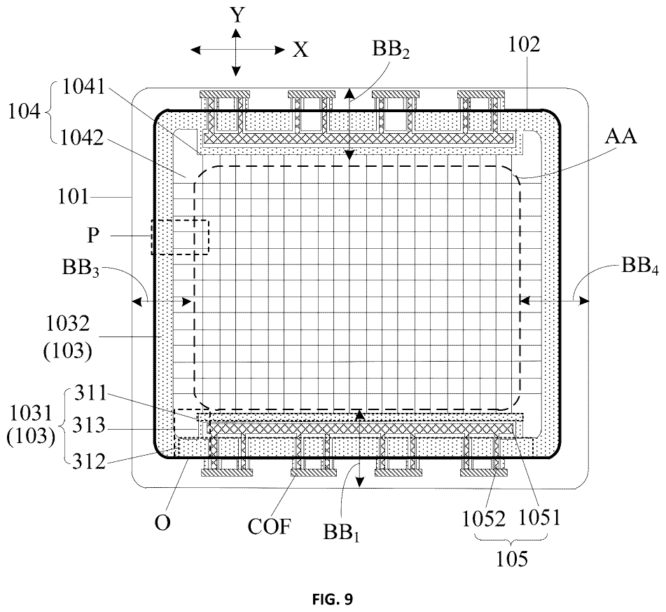

In some embodiments, in the above-mentioned display substrate provided in embodiments of the present disclosure, as shown in FIGS. 1, 9 and 10, the display substrate may also include a second power bus 105 located in the first bezel region BB₁ and/or the second bezel region BB₂, and the second power bus 105 includes a main body portion 1051 extending in the second direction X, and the main body portion 1051 is located in a region enclosed by the first branch 311, the second branch 312 and the third branch 313 to avoid the first sub-power bus 1031 and the second power bus 105 from overlapping and interfering with each other. Continuing to refer to FIGS. 1 and 9, the second power bus 105 can further include at least one lead-out portion 1052 arranged on a side of the main body portion 1051 away from the display region AA, and the lead-out portion 1052 can be electrically connected with the bonding Pad of a circuit board such as a chip on film (COF), and the second branch 312 is disconnected at the position of the lead-out portion 1052 to avoid the first sub-power bus 1031 and the second power bus 105 from overlapping and interfering with each other. In some embodiments, the second branch 312 on both sides of the disconnected position are electrically connected with the first electrode 102 to increase the overlapping area between the second branch 312 and the first electrode 102 and reduce the connection resistance between the second branch 312 and the first electrode 102, thereby reducing the voltage drop and saving energy.

In some embodiments, in the above-mentioned display substrate provided in embodiments of the present disclosure, the second power bus 105 can be electrically connected with the second power line 106 of the display region AA. In some embodiments, in order to avoid the second power line 105 being short-circuited with the first sub-power bus 1031 in the first bezel region BB₁ and/or the second bezel region BB₂, the second power bus 105 and the first sub-power bus 1031 can be insulated from each other and arranged in different layers. In some embodiments, the first power bus 103 is arranged in the first source-drain metal layer (SD₁), and the second power bus 105 is arranged in the second source-drain metal layer (SD₂). In some embodiments, the second power line 106 may be arranged on the same layer as the second power bus 105, for example, the second power line 106 can be also arranged in the second source-drain metal layer (SD₂).

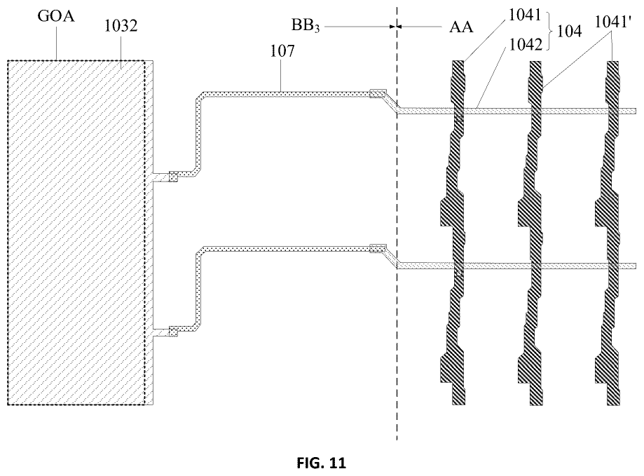

In some embodiments, in the above-mentioned display substrate provided in embodiments of the present disclosure, as shown in FIGS. 1, 9 and 11, the bezel region BB includes a third bezel region BB₃ and a fourth bezel region BB₄ opposite to each other on both sides of the display region AA, and the third bezel region BB₃ and the fourth bezel region BB₄ both extend in the first direction Y; the first power bus 103 includes a second sub-power bus 1032 located in the third bezel region BB₃ and/or the fourth bezel region BB₄, and the second sub-power bus 1032 is electrically connected with the second sub-power line 1042, so that the current of the second sub-power bus 1032 can be diverted to the display region AA surface by means of the second sub-power line 1042. In some embodiments, a connecting line 107 may be provided in the third bezel region BB₃ and/or the fourth bezel region BB₄, and the connecting line 107 is connected between the second sub power bus 1032 and the second sub power line 1042. In some embodiments, to simplify single-layer wiring, the connecting line 107, the second sub-power bus 1032, and the second sub-power line 1042 can be arranged in different layers. In some embodiments, the connecting line 107 is arranged in the first source-drain metal layer (SD₁), the second sub-power bus 1032 is arranged in the second source-drain metal layer (SD₂), and the second sub-power line 1042 is arranged in the third gate metal layer (G3). In some embodiments, as shown in FIG. 11, the display region AA may include at least one signal line 1041′ that is arranged substantially parallel to the first sub-power line 1041. In some embodiments, the signal line 1041′ may be loaded with a low-level power signal VSS. In this case, the signal line 1041′ may be connected in parallel with the first sub-power line 1041. In other embodiments, the signal line 1041′ may be loaded with a high-level power signal VDD, an initialization signal Vinit, etc., which are not limited here.

In some embodiments, the above-mentioned display substrate provided in embodiments of the present disclosure, as shown in FIG. 11, the display substrate may further include a gate drive circuit GOA located in the third bezel region BB₃ and/or the fourth bezel region BB₄, and the gate drive circuit GOA and the second sub-power bus 1042 are arranged in different layers, and the orthographic projection of the gate drive circuit GOA on the base substrate 101 can be located within the orthographic projection of the second sub-power bus 1042 on the base substrate 101, so as to increase the line width of the second sub-power line 1042 as much as possible while ensuring the narrow border effect, reduce the voltage drop, and improve the display uniformity.

Based on the same inventive concept, an embodiment of the present disclosure provides a display device, including the above-mentioned display substrate provided by embodiments of the present disclosure. Since the principle of solving the problem by the display device is similar to the principle of solving the problem by the above-mentioned display substrate, the implementation of the display device provided by embodiments of the present disclosure can refer to the implementation of the above-mentioned display substrate provided by embodiments of the present disclosure, and the repeated parts will not be repeated.

In some embodiments, the display device can be: a projector, a 3D printer, a virtual reality device, a mobile phone, a tablet computer, a television, a monitor, a laptop computer, a digital photo frame, a navigator, a smart watch, a fitness wristband, a personal digital assistant, or any other product or component with a display function. The display device includes but is not limited to: a radio frequency unit, a network module, an audio output & input unit, a sensor, a display unit, a user input unit, an interface unit, a control chip and other components. In some embodiments, the control chip is a central processing unit, a digital signal processor, a system on chip (SoC), etc. For example, the control chip may also include a memory, a power module, etc., and realize power supply and signal input and output functions through additionally provided wires, signal lines, etc. For example, the control chip may also include hardware circuits and computer executable codes. Hardware circuits may include conventional very large scale integration (VLSI) circuits or gate arrays and existing semiconductors or other discrete components such as logic chips, transistors, etc. Hardware circuits may also include field programmable gate arrays, programmable array logic, programmable logic devices, etc. In addition, those skilled in the art will appreciate that the above structure does not constitute a limitation on the above display device provided in embodiments of the present disclosure. In other words, the above display device provided in embodiments of the present disclosure may include more or fewer of the above components, or a combination of certain components, or different component arrangements.

Although the preferred embodiments of the present disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of the disclosure.

Evidently those skilled in the art can make various modifications and variations to the present disclosure without departing from the spirit and scope of the present disclosure. Thus the present disclosure is also intended to encompass these modifications and variations therein as long as these modifications and variations to the present disclosure come into the scope of the claims of the present disclosure and their equivalents.

1. A display substrate, comprising:
a base substrate, comprising a display region and a bezel region on at least one side of the display region;
a first electrode on the base substrate, wherein the first electrode extends from the display region to the bezel region;
a first power bus between a layer where the first electrode is located and the base substrate, wherein the first power bus is in the bezel region and is electrically connected with the first electrode;
a first power line between the layer where the first electrode is located and the base substrate, wherein the first power line is in the display region, is of a mesh structure, and is electrically connected with the first power bus.

2. The display substrate according to claim 1, wherein the first power line comprises:
a plurality of first sub-power lines, extending in a first direction and arranged in a second direction; and
a plurality of second sub-power lines, extending in the second direction and arranged in the first direction;
wherein the first sub-power lines are electrically connected with the second sub-power lines, the first sub-power lines are in a same layer as the second sub-power lines, or the first sub-power lines and the second sub-power lines are in different layers, and the first direction intersects with the second direction.

3. The display substrate according to claim 2, wherein the display region comprises a plurality of pixel columns and a plurality of dummy sub-pixel columns extending in the first direction and arranged in the second direction;
at least one dummy sub-pixel column is arranged between at least one pair of adjacent pixel columns, and the first sub-power lines are located in the dummy sub-pixel columns.

4. The display substrate according to claim 2, wherein the display region comprises a plurality of sub-pixel columns extending in the first direction and arranged in the second direction;
the first sub-power lines are located in at least part of the plurality of sub-pixel columns.

5. The display substrate according to claim 2, wherein the display region comprises a plurality of sub-pixel rows and a plurality of dummy sub-pixel rows extending in the second direction and arranged in the first direction;
at least one dummy sub-pixel row is arranged between at least one pair of adjacent sub-pixel rows, and the second sub-power lines are located in the dummy sub-pixel rows.

6. The display substrate according to claim 2, wherein the display region comprises a plurality of sub-pixel rows extending in the second direction and arranged in the first direction;
the second sub-power lines are located in at least part of the plurality of sub-pixel rows.

7. The display substrate according to claim 2, wherein the bezel region comprises a first bezel region and a second bezel region opposite to each other on both sides of the display region, and the first bezel region and the second bezel region both extend in the second direction;
the first power bus comprises a first sub-power bus in the first bezel region and/or the second bezel region, and the first sub-power bus is electrically connected with the first sub-power line and the first electrode respectively.

8. The display substrate according to claim 7, wherein the first sub-power bus comprises a first branch and a second branch extending in the second direction, and a third branch connecting the first branch and the second branch;
wherein the first branch is arranged adjacent to the display region and is electrically connected with the first sub-power line, and the second branch is arranged on a side of the first branch away from the display region and is electrically connected with the first electrode.

9. The display substrate according to claim 8, wherein a line width of the third branch is larger than a line width of the first branch; and the line width of the third branch is smaller than a line width of the second branch.

10. The display substrate according to claim 8, further comprising: a transfer electrode between a layer where the first power bus is located and the layer where the first electrode is located;
wherein the transfer electrode connects the second branch and the first electrode.

11. The display substrate according to claim 10, further comprising: a second electrode between the layer where the first power bus is located and the layer where the first electrode is located;
wherein the transfer electrode is provided in a same layer and with a same material as the second electrode.

12. The display substrate according to claim 8, further comprising: a second power bus in the first bezel region and/or the second bezel region;
wherein the second power bus comprises: a main body portion extending in the second direction; and
the main body portion is in a region enclosed by the first branch, the second branch and the third branch.

13. The display substrate according to claim 12, wherein the second power bus further comprises at least one lead-out portion on a side of the main body portion away from the display region, and the second branch is disconnected at a position of the lead-out portion.

14. The display substrate according to claim 12, wherein the second power bus and the first sub-power bus are insulated from each other and arranged in different layers.

15. The display substrate according to claim 2, wherein the bezel region comprises a third bezel region and a fourth bezel region opposite to each other on both sides of the display region, and the third bezel region and the fourth bezel region both extend in the first direction;
the first power bus comprises a second sub-power bus in the third bezel region and/or the fourth bezel region, and the second sub-power bus is electrically connected with the second sub-power line.

16. The display substrate according to claim 15, further comprising a connecting line in the third bezel region and/or the fourth bezel region;
wherein the connecting line is connected between the second sub-power bus and the second sub-power line.

17. The display substrate according to claim 16, wherein the connecting line, the second sub-power bus, and the second sub-power line are arranged in different layers.

18. The display substrate according to claim 15, further comprising: a gate drive circuit in the third bezel region and/or the fourth bezel region;
wherein the gate drive circuit and the second sub-power bus are arranged in different layers, and an orthographic projection of the gate drive circuit on the base substrate is located within an orthographic projection of the second sub-power bus on the base substrate.

19. The display substrate according to claim 2, further comprising: a first active layer, a first gate metal layer, a second gate metal layer, a second active layer, a third gate metal layer, a first source-drain metal layer, a second source-drain metal layer and a third source-drain metal layer sequentially arranged on the base substrate and insulated from each other;
wherein the first sub-power line and the second sub-power line are arranged in at least one of: the first gate metal layer, the second gate metal layer, the third gate metal layer, the first source-drain metal layer, the second source-drain metal layer or the third source-drain metal layer.

20. A display device, comprising the display substrate according to claim 1.
